(19) United States
(12) Patent Application Publication
(10) Pub. No.: US 2015/0380561 A1
(43) Pub. Date: Dec. 31, 2015

(54) METAL OXIDE TFT STABILITY IMPROVEMENT

(71) Applicant: APPLIED MATERIALS, INC., Santa Clara, CA (US)

(72) Inventors: Tae K. WON, San Jose, CA (US); Soo Young CHOI, Fremont, CA (US); Dong-kil YIM, Pleasanton, CA (US); Beom Soo PARK, San Jose, CA (US)

(21) Appl. No.: 14/765,528

(22) PCT Filed: Feb. 5, 2014
(86) PCT No.: PCT/US2014/014951

§ 371 Date: Aug. 3, 2015

Related U.S. Application Data
(60) Provisional application No. 61/771,257, filed on Mar. 1, 2013.

(51) Int. Cl. H01L 29/786; H01L 29/24; H01L 29/51; H01L 21/02; H01L 29/66; H01L 29/49

(52) U.S. Cl. CPC H01L 29/7869; H01L 29/66969; H01L 29/78606; H01L 29/4908; H01L 29/51; H01L 21/02554; H01L 21/02565; H01L 29/24; H01L 21/0262; H01L 21/02126

(57) ABSTRACT

A metal oxide thin film transistor incorporating reduced hydrogen silicon-containing layers and methods of making the same are disclosed herein. The thin film transistor can include a substrate, a metal oxide semiconductor layer, a substantially hydrogen free channel interface layer and a cap layer comprising silicon formed over the channel interface layer. The method for making a thin film transistor can include depositing a metal oxide semiconductor layer over a substrate, activating a deposition gas comprising SiF₄ to create an activated deposition gas, delivering the activated deposition gas to the substrate to deposit a channel interface layer comprising SiOF and depositing a cap layer over the channel interface layer and the metal oxide thin film transistor layer.

### BACKGROUND OF THE INVENTION

1. Field of the Invention

Embodiments described herein generally relate to reducing hydrogen in dielectric and passivation layers. More specifically, embodiments described herein generally relate to reducing hydrogen in silicon-containing layers for use in metal oxide thin film transistors (TFTs).

2. Description of the Related Art

Metal oxide semiconductors, such as zinc oxide (ZnO) and indium gallium zinc oxide (IGZO) are attractive for device fabrication due to their high carrier mobility, low processing temperatures, and optical transparency. TFTs made from metal oxide semiconductors (MO-TFTs) are particularly useful in active-matrix addressing schemes for optical displays. The low processing temperature of metal oxide semiconductors allows the formation of display backplanes on inexpensive plastic substrates such as polyethylene terephthalate (PET) and polyethylene naphthalate (PEN). The transparency of oxide semiconductor TFTs leads to improved pixel apertures and brighter displays.

The MO-TFT's stability and performance is very sensitive to hydrogen content, both as incorporated into the MO-TFT itself and incorporated into contacting layers. The contacting layers can include a channel interface layer or a bulk layer. The contacting layers include CVD deposited films, such as silicon oxide (SiO), silicon oxynitride (SiON), silicon nitride (SiN), etc. In many semiconductors, interstitial hydrogen (hydrogen between layers) has been found to act as an amphoteric impurity (an impurity that can act as a donor or an acceptor depending on the semiconductor material it is added to). Thus, in p-type materials, hydrogen generally acts as a donor, and, in n-type materials, hydrogen generally as an acceptor. In MO-TFTs, however, hydrogen can be deleterious. Conventional plasma enhanced chemical vapor deposition (PECVD) films create a very high hydrogen content in the film. For example, SiO deposited by conventional PECVD contains approximately 4% hydrogen and SiN deposited by conventional PECVD contains approximately 35% hydrogen. The hydrogen content of conventional PECVD films induces a high threshold voltage shift (Vₜₕ shift) under voltage/light bias conditions.

Therefore, there is a need in the art for lower hydrogen content in films for use with MO-TFTs.

### SUMMARY OF THE INVENTION

The embodiments described herein generally relate to substantially hydrogen free films for use with MO-TFTs and methods for making the same. In one embodiment, a thin film transistor can include a substrate; a metal oxide semiconductor layer formed over a portion of the surface of the substrate; a channel interface layer comprising silicon oxyfluoride (SiOF) in contact with the amorphous metal oxide layer, wherein the channel interface layer is substantially free of hydrogen; and a cap layer comprising silicon formed over the interface layer.

In another embodiment, a method for making a thin film transistor includes positioning a substrate in a processing chamber; depositing a metal oxide semiconductor layer over a portion of the surface of the substrate, the metal oxide semiconductor layer comprising a zinc oxide; activating a deposition gas comprising SiF₄ using MW-PECVD to create an activated deposition gas, wherein the deposition gas does not include hydrogen; delivering the activated deposition gas to the substrate to deposit a channel interface layer comprising SiOF over the metal oxide thin film transistor layer; and depositing a cap layer over the channel interface layer and the metal oxide thin film transistor layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 a cross-sectional view of a schematic MW-PECVD chamber according to one embodiment of the invention;

FIGS. 2A-2H are cross-sectional views of a MO-TFT film stack with a hydrogen free channel interface layer at various stages of processing according to one embodiment; and

FIG. 3 is a flow diagram of a method for depositing a MO-TFT film stack, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Higher stability MO-TFT structures and methods for making the same are disclosed herein. Due to hydrogen's donor activity in MO-TFT structures, hydrogen concentration in both the MO-TFT layer and the encapsulation layer, which can include the channel interface layer and cap layer, should be limited. To accomplish this, a passivation layer can be deposited using a deposition gas which is activated by microwave PECVD (MW-PECVD). In embodiments herein, gases activated by MW-PECVD can include gases that are ignited directly by the MW-PECVD or activated indirectly, such as activation of the deposition gas by delivering a remote plasma formed from an inert gas or a constituent gas of the deposition gas. In one or more embodiments, the passivation layer can be a multilayer structure comprising at least a channel interface layer and a cap layer. The channel interface layer is the lowermost layer and forms the interface between the passivation layer and the metal oxide semiconductor. Typical channel interface layers can include highly porous silicon containing dielectric layers, such as silicon oxyfluoride (SiOF). The cap layer is formed over the channel interface layer and serves to seal the porous channel interface layer. Typical cap layers can include dense silicon containing dielectric layers, such as silicon oxide (SiOₓ), silicon oxynitride (SiON) and silicon nitride (SiN). Not only does the deposition of the overlying layers occur at lower temperatures when using MW-PECVD than an equivalent deposition using standard PECVD but hydrogen incorporation into the resulting layer is also reduced. The embodiments disclosed herein are more clearly described with reference to the figures below.

The embodiments described below can be practiced in a PECVD chamber available from AKT America, Inc., a subsidiary of Applied Materials, Inc., Santa Clara, Calif. It is to be understood that the invention has applicability in other chambers as well, including apparatus available from other manufacturers.

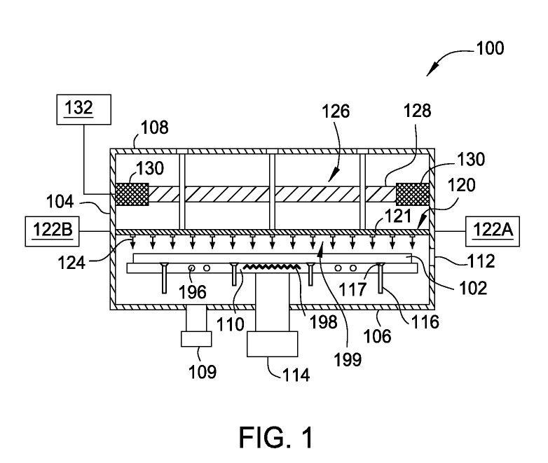

FIG. 1 is a cross-sectional view of a schematic MW-PECVD chamber according to one embodiment. A process chamber 100 is configured to allow one or more films to be deposited onto a substrate 102 without removing the substrate 102 from the process chamber 100. While the description below will be made in reference to a MW-PECVD chamber, particularly to a horizontal-type chamber where the microwave and gas feeding sources are disposed above a horizontally positioned substrate susceptor for a horizontal deposition process, it is to be understood that the present invention may be applied to those vertical-type deposition chambers with the microwave line sources vertically attached to chamber walls of the process chamber, and a vertically positioned substrate susceptor for supporting a substrate in vertical configuration. In addition, it should be noted that the figures and the corresponding description are merely exemplary, and any individual hardware feature described in a single embodiment can be combined with any of other embodiments described in the specification.

The substrate 102 may be, among others, a thin sheet of metal, plastic, organic material, silicon, glass, quartz, or polymer materials. In one embodiment, the substrate 102 is a glass substrate upon which a silicon-containing layer will be deposited. In other embodiments, the substrate 102 may be doped or otherwise modified glass substrate, such as a glass substrate with a MO-TFT layer formed thereon.

The process chamber 100 generally includes chamber walls 104, a chamber bottom 106 and a chamber lid 108 which define a process volume 199 therein. The process volume 199 is coupled to a vacuum system 109 and has a substrate susceptor 110 disposed therein. The process volume 199 is accessed through a slit valve opening 112 such that the substrate 102 may be transferred in and out of the process chamber 100. The chamber walls 104, chamber bottom 106, and the chamber lid 108 may be fabricated from a unitary block of aluminum or other material compatible for plasma processing. The chamber lid 108 is supported by the chamber walls 104 and can be removed to service the process chamber 100. The substrate susceptor 110 may be coupled to an actuator 114 to raise and lower the substrate susceptor 110.

The substrate susceptor 110 may optionally include heating and/or cooling elements to maintain the substrate susceptor 110 at a desired temperature, such as a resistive heater 198 and/or cooling fluid conduits 196. Lift pins 116 are moveably disposed through the substrate susceptor 110 to controllably support the substrate 102 prior to placement onto the substrate susceptor 110 and after removal from the substrate susceptor 110.

The major components of the process chamber 100 in accordance with the present invention may include, among others, a gas feeding source 120 and a microwave source 126. The microwave source 126 may include one or more microwave antennas 128 that are configured to be parallel to the longitudinal direction of the gas feeding source 120. The gas feeding source 120 may be located between the microwave source 126 and the substrate 102.

The gas feeding source 120 may include an array of gas feeding lines 121 that are configured to receive one or more precursor gases and/or carrier gases from a gas source 122A and/or gas source 122B. The microwave source 126 may be located between the gas feeding source 120 and the top (e.g., the chamber lid 108) of the process chamber 100. The microwave source 126 generally includes the microwave antennas 128 and a coupling mechanism 130 connected to the microwave antennas 128. The microwave source 126 may be coupled to ground. While only one microwave antenna 128 is shown, it is contemplated that the number of the microwave antennas 128 may be increased depending upon the size of the substrate.

A microwave supply 132 is connected to the microwave source 126 and can deliver microwave power to the antennas 128. In operation during a process, such as a deposition process, the microwaves travel along the microwave antennas 128 and go through a high attenuation by converting electromagnetic energy into plasma energy which ignites a plasma within the process volume. Radical species generated by the plasma disassociates the reactive precursors (e.g., SiH₄, SiF₄, N₂O, O₂, N₂ or combinations thereof) coming from the gas feeding lines 121, which are directed toward the substrate 102 (as indicated by arrows 124) and uniformly distributed across the substrate surface to form a film (e.g. SiOx, silicon oxynitride (SiON), SiN or SiOF) on the substrate 102 that is held by the substrate susceptor 110. Pressure within the chamber during deposition is controlled by a vacuum system 109.

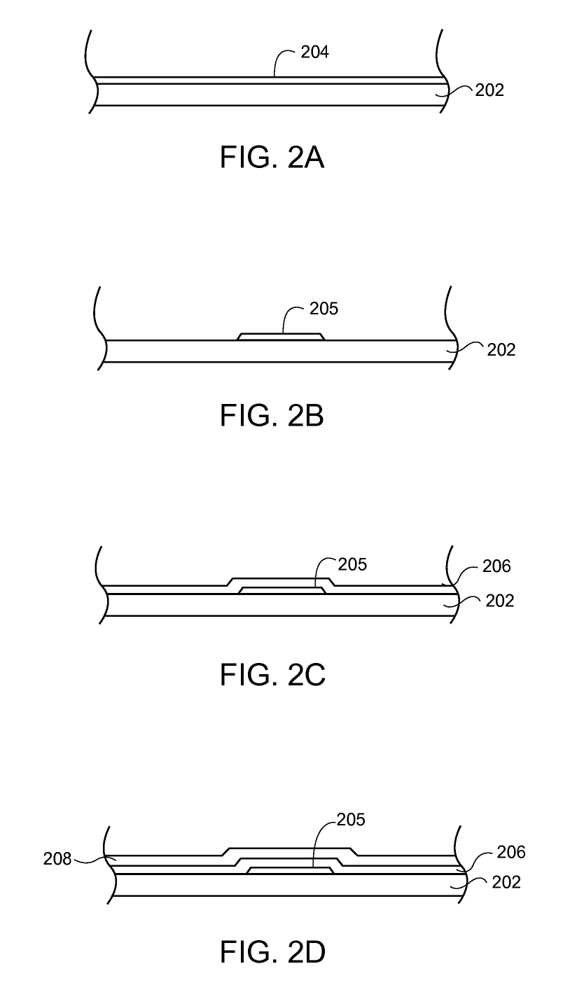

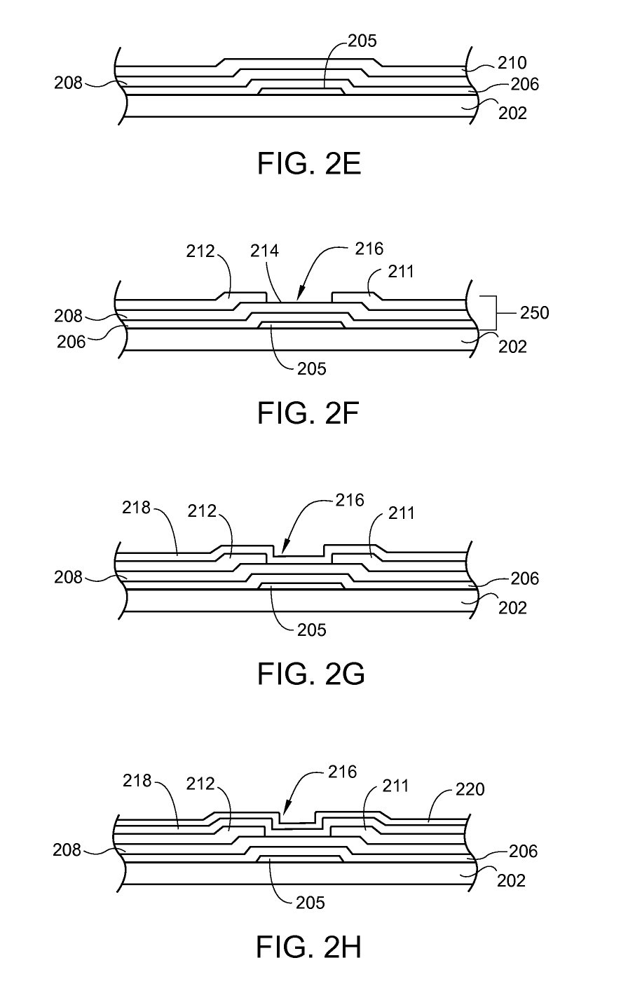

FIGS. 2A-2H are schematic illustrations of an MO-TFT according to one embodiment. As shown in FIG. 2A, the MO-TFT is fabricated by depositing a conductive layer 204 over a substrate 202. Suitable materials that may be utilized for the substrate 202 include but are not limited to glass, plastic, and semiconductor wafers. Suitable materials that may be utilized for the conductive layer 204 include but are not limited to chromium, molybdenum, copper, aluminum, tungsten, titanium, and combinations thereof. The conductive layer 204 may be formed by physical vapor deposition (PVD) or other suitable deposition methods, such as electroplating, electroless plating or chemical vapor deposition (CVD).

In FIG. 2B, the conductive layer 204 is patterned to form a gate electrode 205. The conductive layer 204 can be patterned by forming either a photolithographic mask or a hard mask over the conductive layer 204 and exposing the conductive layer 204 to an etchant. The conductive layer 204 may be patterned by exposing the exposed portions of the conductive layer 204 to a wet etchant or to an etching plasma. In one embodiment, the etching plasma can comprise gases selected from SF₆, O₂, Cl₂, or combinations thereof.

As shown in FIG. 2C, after the gate electrode 205 has been formed, a gate dielectric layer 206 is deposited thereover. The gate dielectric layer 206 can include SiOF, SiN, SiOx, and silicon oxynitride (SiON). Additionally, while shown as a single layer, it is contemplated that the gate dielectric layer 206 may comprise multiple layers, each of which may comprise a different chemical composition. Suitable methods for depositing the gate dielectric layer 206 include conformal deposition methods such as MW-PECVD, PECVD, CVD and atomic layer deposition (ALD). The gate dielectric layer 206 should be deposited with minimal hydrogen. In one embodiment, the gate dielectric layer 206 is composed of at least one layer of SiOF deposited by MW-PECVD. In this embodiment, the SiOF layer has a hydrogen concentration of less than 1 atomic percent, such as no detectable hydrogen.

As shown in FIG. 2D, a high mobility active layer 208 is deposited as the semiconductor layer. Suitable materials that may be used for the high mobility active layer 208 include IGZO and zinc oxide. The active layer 208 may be deposited by suitable deposition methods such as PVD. In one embodiment, the PVD may comprise applying a DC bias to a rotary cathode.

As shown in FIGS. 2E and 2F, a conductive layer 210 may be deposited over the active layer 208. The conductive layer 210 may be formed by PVD or other suitable deposition methods such as electroplating, electroless plating or CVD. In FIG. 2F, the conductive layer 210 is patterned to form a source electrode 211 and a drain electrode 212 by a back channel etch process. The patterning may occur by forming either a photolithographic mask or a hard mask over the conductive layer 210 and exposing the exposed portions of the conductive layer 210 to an etchant. The conductive layer 210 may be patterned by exposing the exposed portions of the conductive layer 210 to a wet etchant or to an etching plasma. In one embodiment, the conductive layer 210 may be patterned by etching areas of the conductive layer 210 that are not covered by a mask with an etching plasma comprising etchants such as SF₆, O₂, and combinations thereof. In forming the source electrode 211 and the drain electrode 212, a portion of the active layer 208 is exposed creating an exposed portion 214. The exposed portion 214 is between the source electrode 211 and drain electrode 212. The area between the source electrode 211 and drain electrode 212 is referred to as the active channel 216. The combined gate electrode 205, the gate dielectric layer 206, the high mobility active layer 208, the source electrode 211 and the drain electrode 212 are referred to herein as the metal oxide thin film transistor (MO-TFT) layer 250.

In FIG. 2G, a channel interface layer 218 is deposited over the active channel 216, the source electrode 211 and drain electrode 212. In one embodiment, the channel interface layer 218 that is in contact with the exposed portion 214 of the active layer 208 is a low hydrogen containing oxide, such as SiOF. The channel interface layer 218 can be deposited to a thickness of from 20 Å to 3000 Å. In embodiments which employ SiOF as the channel interface layer 218, hydrogen concentration is approximately zero, thus preventing hydrogen interaction with the exposed portion 214 of the active layer 208. SiOF can be deposited using MW-PECVD using a deposition gas including SiF₄ and N₂O, O₂ an inert carrier gas or combinations thereof. As depicted, the deposition of the channel interface layer 218 is substantially conformal across the surface of the active channel 216, the source electrode 211 and drain electrode 212. Though the low hydrogen containing oxide, specifically SiOF, is described as being deposited using MW-PECVD, other deposition methods are applicable to depositing a SiOF layer. In one embodiment, CCP-PECVD is used to deposit a SiOF layer using the deposition gases (e.g., SiF₄ and N₂O) described herein.

In FIG. 2H, a cap layer 220 is formed over the surface of the channel interface layer 218. The channel interface layer 218, though low in hydrogen, is generally not used as a single layer on the device due to low film density. The low film density, due in part to the porous nature of SiOF, allows hydrogen from the environment to diffuse into the channel interface layer 218. To prevent the hydrogen diffusion, the cap layer 220 is generally formed over the channel interface layer 218 and can comprise one or more additional layers of a low hydrogen containing oxide (e.g., SiOx, SiON, SiN or combinations thereof). The cap layer 220 can be deposited to a thickness of from 50 Å to 3000 Å, such as from 100 Å to 1000 Å. Though the channel interface layer 218 and the cap layer 220 are described as a single layer, further embodiments of the channel interface layer 218 or the cap layer 220 can include more than one layer and the layers may be of different chemical composition than any previous layer.

When silicon oxide is used as the cap layer 220, the silicon oxide can be deposited either by MW-PECVD, PECVD or PVD. The plasma damage associated with PVD and the hydrogen incorporating from PECVD can be reduced or avoided using MW-PECVD. In one embodiment, MW-PECVD is used to deposit a SiO₂ cap layer. MW-PECVD deposition provides highly conformal deposition results, less plasma damage to the deposited films and reduction of hydrogen concentration in the deposited layer. MW-PECVD silicon oxide is normally deposited with SiH₄+O₂ or SiH₄+N₂O as the source gases, where the former provides better film quality than the latter.

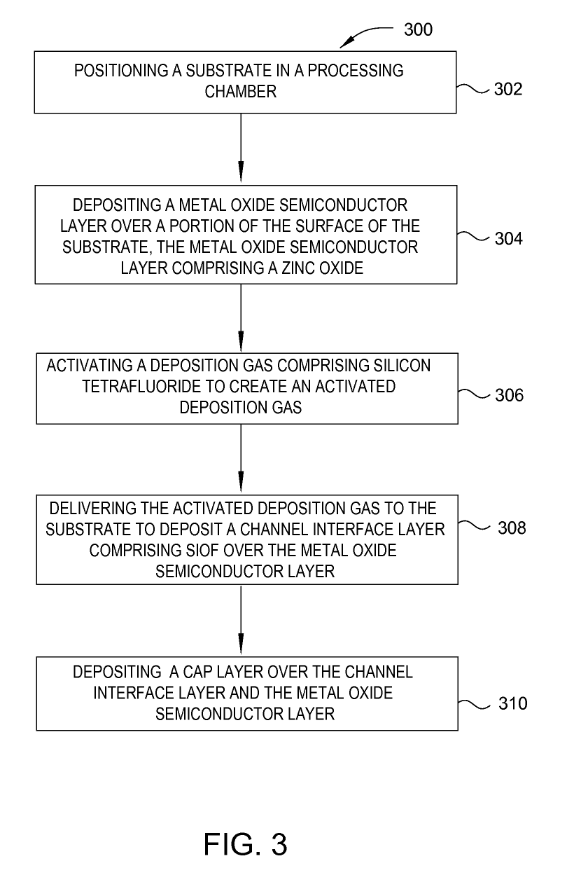

FIG. 3 is a flow diagram of a method for depositing a MO-TFT film stack, according to one embodiment. The method 300 begins with a substrate being positioned in a processing chamber, as in step 302. Suitable substrate materials can include but are not limited to glass, quartz, sapphire, germanium, plastic or composites thereof. Additionally, the substrate can be a relatively rigid substrate or a flexible substrate. Further, any suitable substrate size may be processed. Examples of suitable substrate sizes include substrate having a surface area of about 2000 centimeter square or more, such as about 4000 centimeter square or more, for example about 10000 centimeter square or more. In one embodiment, a substrate having a surface area of about 50000 centimeter square or more may be processed. The embodiments described below are in relation to a 5500 centimeter square substrate.

A metal oxide semiconductor layer is deposited over a portion of the surface of the substrate, as in step 304. The metal oxide semiconductor layer can be deposited as described with reference to FIG. 2 including the combined gate electrode, the gate dielectric layer, the high mobility active layer, the source electrode and the drain electrode. The high mobility active layer can be an amorphous metal oxide layer, such as IGZO or another zinc oxide layer. The gate dielectric layer can be a low hydrogen dielectric layer, such as SiOₓ deposited by MW-PECVD or SiOF deposited by either MW-PECVD or PECVD using RF plasma. In other embodiments, the gate dielectric layer can be composed of SiOₓ, SiN, SiON or another dielectric as known in the art for use with thin film transistors.

A deposition gas comprising SiF₄ is then activated using PECVD or MW-PECVD to create an activated deposition gas, as in step 306. When depositing SiOF by either MW-PECVD or standard PECVD, deposition gases can include SiF₄, SiH₄, N₂O, O₂ or combinations thereof. In one embodiment, SiOF is deposited by RF PECVD using a deposition gas including SiF₄, SiH₄ and O₂. In this embodiment, the SiH₄ is believed to compensate for the relatively low electron density of the RF plasma as compared to the MW plasma, thus allowing for formation of the SiOF layer.

The microwave power used in embodiments herein can be a relatively high power, such as a microwave power between 3000 W and 5000 W, for example a microwave power of 4000 W. The microwave power may be directed by one or more antennas, such as six antennas. The antennas can be positioned so as to maintain the plasma until it reaches the substrate.

The activated deposition gas is then delivered to the substrate to deposit a channel interface layer comprising SiOF over the metal oxide semiconductor layer, as in step 308. The activated deposition gas can be delivered to the substrate to deposit a channel interface layer over the metal oxide semiconductor layer. The channel interface layer will be deposited conformally over the active channel and the source and drain electrodes, creating a hydrogen free channel interface layer. The channel interface layer comprising SiOF is highly porous, so the deposited layer should be maintained in hydrogen free conditions prior to deposition of any subsequent layers. The channel interface layer can have a thickness of from 20 Å to 3000 Å. When depositing the channel interface layer using MW-PECVD, the temperature for deposition can be from 200° C. to 350° C., such as 230° C. to 330° C. The channel interface layer can comprise more than one layer, such as a channel interface layer with three layers.

A cap layer is then deposited over the channel interface layer and the metal oxide semiconductor layer, as in step 310. The cap layer can be a layer composed of SiOx, SiON, SiN or combinations thereof. The cap layer can have a thickness of from 50 Å to 3000 Å. The cap layer, like the channel interface layer, can comprise more than one layer. Further, each layer of the cap layer can be of a different composition than any other layer of the cap layer. In one embodiment, the cap layer includes a SiO layer formed over the channel interface layer, a SiN layer formed over the SiO layer and an SiO layer formed over the SiN layer. Further, each of the layers of the cap layer may have a different thickness than other layers in the cap layer.

The cap layer is deposited using a silicon containing precursor and an oxidizing precursor. Silicon-containing precursors can include silicon hydrides, such as SiH₄. The silicon-containing precursor can be flowed into a processing chamber for deposition of a SiOₓ film. In an exemplary chamber, flow rates for silicon hydrides, such as SiH₄, can be from 100 sccm to 500 sccm, for example flow rates from 150 sccm to 450 sccm, such as a flow rate of 350 sccm. When the cap layer is deposited using MW-PECVD, the deposition temperature can be between 100° C. and 350° C., such as temperatures between 130° C. and 200° C., for example 130° C.

The oxidizing precursor can include diatomic oxygen (O₂), ozone (O₃), nitrous oxide (N₂O) or other oxidizing gases. The oxidizing precursor can be flowed into a processing chamber alongside silicon hydrides and silicon halides. In an exemplary chamber, such as the one described above, flow rates for O₂, O₃ or N₂O when deposited with silicon hydrides can be from 2000-5000 sccm, such as a flow rate of 3500 sccm. In another embodiment, flow rates for O₂ or O₃ when deposited with silicon halides can be from 5000 to 7000 sccm, such as a flow rate of 5500 sccm. In another embodiment, flow rates for N₂O when deposited with silicon halides can be from 3000 to 7000 sccm, such as a flow rate of 4000 sccm.

By using lower temperatures, such as temperatures between 100° C. and 350° C., such as between 130° C. and 200° C., a largely hydrogen-free and pinhole-free layer can be deposited from microwave activated precursors while avoiding the some of the deleterious effects of using silane (SiH₄) and some oxidizing precursors. Temperature will preferably be higher when using silicon tetrafluoride (SiF₄), as a higher quality and higher deposition rate SiOF can be deposited at temperatures between 200° C. and 350° C., such as from 230° C. to 330° C.

MW-PECVD creates a lower hydrogen concentration in the deposited layer than equivalent layers deposited by PECVD using RF plasma. Without intending to be bound by theory, MW plasma induces a higher electron density than RF plasma. The higher electron density of the MW plasma contributes to break weak Si—H, N—H, O—H bonding in the deposition gases. By breaking these bonds, hydrogen deposition in the SiOₓ, SiOF, or SiN film during film formation is reduced as compared to the RF plasma deposition of the same layers. In standard embodiments, the RF PECVD films have high hydrogen content such as approximately 4% in SiO film and approximately 35% in SiN film, whereas MW-PECVD films have very low comparative hydrogen content, such as approximately 1% in SiO film and approximately 16% in SiN film.

Deposited silicon oxide SiOₓ can include SiO₂, SiO, or combinations thereof. The formation of the SiOₓ layer can be controlled by deposition factors such as temperature, pressure, flow rate of reactant gas and amount of microwave power applied among other factors. Pin-hole-free SiOₓ layers help maintain MO-TFT integrity. Pin hole density is strongly correlated with RF power and weakly with pressure.

The cap layer acts to prevent hydrogen containing species from penetrating the porous SiOF layer. Without intending to be bound by theory, reduction in hydrogen concentration is important in the creation of various features on a substrate, such as gates. Hydrogen is a ubiquitous impurity in SiOₓ and is believed to be responsible for fixed charge in the oxide. Release of hydrogen during operation is believed to be responsible for the creation of defects such as trap generation which can lead to intrinsic dielectric breakdown. Further, hydrogen incorporation into the MO-TFT layer is believed to create a high threshold voltage shift. As such, reduced hydrogen concentration is believed to be important to avoidance of such defects.

### CONCLUSION

Embodiments described herein relate to the formation of a MO-TFT with reduced hydrogen in the dielectric and passivation layers. Metal oxides such as IGZO and zinc oxides are sensitive to the presence of hydrogen. As hydrogen is a ubiquitous impurity in many dielectric layers, reduction of hydrogen is important to MO-TFT stability and consistency. By employing microwave plasma, silicon containing layers with significantly reduced hydrogen concentration, such as SiOF, SiOx and SiN, can be deposited at various stages of MO-TFT formation. The channel interface layer can be substantially composed of SiOF. Subsequent high density layers, such as SiOx, can be deposited as a cap layer to prevent hydrogen diffusion into the channel interface layer.

While the foregoing is directed to embodiments of the present invention, other and further embodiments of the invention may be devised without departing from the basic scope thereof, and the scope thereof is determined by the claims that follow.

1. A thin film transistor comprising:
a substrate having a first surface;
a metal oxide semiconductor layer formed over a portion of the first surface of the substrate;
a channel interface layer in contact with the metal oxide semiconductor layer, the channel interface layer comprising silicon oxyfluoride (SiOF), wherein the channel interface layer comprises less than 1 atomic percent hydrogen; and
a cap layer formed over the channel interface layer, the cap layer comprising silicon.

2. The thin film transistor of claim 1, wherein the cap layer comprises of silicon nitride or silicon oxide.

3. The thin film transistor of claim 2, wherein the cap layer comprises of silicon nitride and contains less than 16 atomic percent hydrogen.

4. The thin film transistor of claim 1, wherein the hydrogen content of the cap layer is not greater than 1 atomic percent.

5. The thin film transistor of claim 1, wherein the channel interface layer comprises more than one layer, and wherein at least one layer of the channel interface comprises SiOF.

6. The thin film transistor of claim 1, wherein each of the channel interface layer and the cap layer are between 20 Å and 3000 Å.

7. The thin film transistor of claim 1, wherein the cap layer comprises of two or more layers.

8. The thin film transistor of claim 1, wherein the metal oxide semiconductor layer is deposited over a gate dielectric layer, the gate dielectric layer consisting of SiOF.

9. A method for making a thin film transistor comprising:
positioning a substrate in a processing chamber;
depositing a metal oxide semiconductor layer over a portion of the surface of the substrate, the metal oxide semiconductor layer comprising zinc oxide;
activating a deposition gas to create an activated deposition gas, the deposition gas comprising SiF₄;
delivering the activated deposition gas to the substrate to deposit a channel interface layer over the metal oxide semiconductor layer, wherein the channel interface layer contains less than 1 atomic percent hydrogen; and
depositing a cap layer over the channel interface layer and the metal oxide semiconductor layer.

10. The method of claim 9, wherein the channel interface layer is deposited at temperatures less than 250 degrees Celsius.

11. The method of claim 9, wherein the cap layer is deposited using a deposition gas mixture comprising SiH₄, O₂, N₂O or combinations thereof.

12. The method of claim 9, wherein the cap layer is deposited using a deposition gas mixture comprising SiH₄, SiF₄, NH₃, N₂, H₂ or combinations thereof.

13. The method of claim 9, wherein the channel interface layer comprises less than 1 atomic percent hydrogen.

14. The method of claim 9, wherein the cap layer comprises silicon nitride or silicon oxide.

15. The method of claim 9, further comprising depositing a gate dielectric layer over the substrate, the gate dielectric layer comprising SiOF.

16. The method of claim 9, wherein the channel interface layer is deposited using a deposition gas mixture comprising SiF₄, O₂, N₂O or combinations thereof.

17. The method of claim 9, wherein the cap layer is deposited using microwave PECVD.

18. A thin film transistor comprising:
a substrate having a first surface;
a gate electrode formed over the first surface;
a gate dielectric layer formed over the gate electrode, the gate dielectric layer comprising SiOF;
a metal oxide semiconductor layer formed over the gate dielectric layer, the metal oxide semiconductor layer comprising zinc oxide;
a channel interface layer in contact with the metal oxide semiconductor layer, the channel interface layer comprising silicon oxyfluoride (SiOF), wherein the channel interface layer comprises less than 1 atomic percent hydrogen; and
a cap layer formed over the channel interface layer, the cap layer comprising silicon nitride or silicon oxide.

19. The thin film transistor of claim 18, wherein the cap layer comprises of silicon nitride and contains less than 16 atomic percent hydrogen.

20. The thin film transistor of claim 18, wherein each of the channel interface layer and the cap layer are between 20 Å and 3000 Å.
